(19) United States
(12) Patent Application Publication
(10) Pub. No.: US 2002/0075040 A1
(43) Pub. Date: Jun. 20, 2002

(54) Method and device for configuring an electrical circuit

(76) Inventor: Roderick McConnell, Munchen (DE)

Correspondence Address: LERNER AND GREENBERG, P.A., Post Office Box 2480, Hollywood, FL, 33022-2480, US

(21) Appl. No.: 09/932,877

(22) Filed: Aug. 20, 2001

(30) Foreign Application Priority Data
Aug. 18, 2000 (DE) 100 40 542.8

(51) Int. Cl. H03K 19/00; H01L 25/00

(52) U.S. Cl. 326/101

(57) ABSTRACT

In the circuit configuration described, corresponding parts of the functions and/or structures of a first circuit that performs only a first task and of a second circuit that performs only a second task are identified and used as a basis for the circuit to be configured. The functional parts and/or circuit parts of the first and of the second circuit, to which it has not been possible to assign any corresponding components in the respective other circuit, and switching devices which are used for configuration are added.

### BACKGROUND OF THE INVENTION

1. Field of the Invention

The present invention relates to a method and a device for configuring an electrical circuit, which can perform either a first task or a second task.

Electrical circuits which can perform either a first task or a second task are, for example, configurable hardware blocks, are known from Published, Non-Prosecuted German Patent Applications DE 198 43 663 A1, and DE 198 43 647 A1.

Such hardware blocks, and other hardware blocks, can be configured in accordance with the method described in Published, Non-Prosecuted German Patent Application DE 198 43 640 A1, for example, and perform a wide variety of tasks depending on their configuration.

Employing universally usable configurable hardware blocks and providing a relatively large number of such hardware blocks enables them to perform any desired number of tasks, of any desired complexity, at relatively low cost.

However, when such hardware blocks are used, it is not unusual for a situation to arise in which the existing hardware blocks are not used, or are used only partially; there are always hardware blocks or hardware block components that are never used. The presence of excess hardware blocks or hardware block components has the negative effect that configurations containing such hardware blocks are larger and more expensive than would be respectively necessary.

### SUMMARY OF THE INVENTION

It is accordingly an object of the invention to provide a method and a device for configuring an electrical circuit which overcome the above-mentioned disadvantages of the prior art devices and methods of this general type, which are configured therewith to contain only a small number of excess circuit parts, or none at all, and the existing circuit parts can be used to an optimum degree.

With the foregoing and other objects in view there is provided, in accordance with the invention, a method for configuring an electrical circuit that can perform optionally a first task and a second task. The method includes identifying common functional parts and/or common circuit parts common between a first circuit performing only the first task and a second circuit performing only the second task, and using the common functional parts and/or the common circuit parts as a basis for configuring the electrical circuit. Further functional parts and/or further circuit parts of the first circuit and of the second circuit are added, which do not belong to the common functional parts and the common circuit parts. Components are added which influence and/or logically link the further functional parts, the further circuit parts, the common functional parts and the common circuit parts in such a way that the parts operate and cooperate so as to perform the functions of the first circuit and of the second circuit.

Such a circuit configuration makes it possible for the circuit not to contain any parts that are never used, and for the circuit to contain as few parts as possible with an identical or corresponding function.

In accordance with an added mode of the invention, there are the steps of identifying a function of the electrical circuit to be configured, and making a synthesis of the electrical circuit to be configured on a basis of the function.

In accordance with an additional mode of the invention, the step of identifying the common functional parts and the common circuit parts include the steps of designing the first circuit which performs the first task, designing the second circuit which performs the second task, and searching through the first and second circuits for circuit parts with identical or corresponding functions.

In accordance with another mode of the invention, there is the step of using switching elements as the components which influence and/or logically link the further and common functional parts and the common and further circuit parts.

In accordance with a further mode of the invention, there is the step of using multiplexers as the switching elements.

With the foregoing and other objects in view there is provided, in accordance with the invention, a device for configuring an electrical circuit that can perform optionally a first task and a second task. The device contains means for identifying common functional parts and common circuit parts common between a first circuit performing only the first task and a second circuit performing only the second task. The common functional parts and the common circuit parts are used as a basis for the electrical circuit to be designed. Means are provided for adding further functional parts and further circuit parts of the first and of the second circuit, which do not belong to the common functional parts and the common circuit parts. Means are provided for adding components that influence and/or logically link the further and common functional parts and the further and common circuit parts in such a way that they operate and cooperate so as to perform the functions of the first circuit and of the second circuit.

Other features which are considered as characteristic for the invention are set forth in the appended claims.

Although the invention is illustrated and described herein as embodied in a method and a device for configuring an electrical circuit, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a schematic diagram of a structure of a first circuit that performs only a first task according to the invention;

FIG. 2 is a schematic diagram of the structure of a second circuit which performs only a second task;

FIG. 3 is a schematic diagram of the structure of a circuit that performs both the first task and the second task; and

FIG. 4 is a flow chart of functions performed by a programmable device for implementing the invention.

### DESCRIPTION OF THE PREFERRED EMBODIMENTS

In all the figures of the drawing, sub-features and integral parts that correspond to one another bear the same reference symbol in each case. A method is described below with reference to a purely combinatorial Boolean logic, i.e. a logic in which the times at which the individual operations are carried out does not play any role. However, it is to be noted at this point that the method described can also be used to configure sequential logic circuits and any other desired digital or analog circuits.

In the example in question, the circuit to be configured will be able to perform either a first task or a second task. The circuit to be configured can, however, also be a circuit that can perform more than two different tasks in an alternating fashion.

The method in question contains, as described below in detail, the steps of identifying corresponding parts of functions and/or of structures of a first circuit that performs only a first task and of a second circuit that performs only a second task. The common functional parts and/or circuit parts are used as a basis for the circuit to be configured by adding the functional parts and/or circuit parts of the first and of the second circuit, to which it has not been possible to assign any corresponding common functional parts and/or circuit parts in the respective other circuit. Components are then added which influence and/or logically link the existing functional parts and/or circuit parts in such a way that they operate and cooperate either as in the first circuit or as in the second circuit.

The aforesaid steps can be implemented in different ways.

In a first possible way described below, the circuit is configured by identifying the function of the circuit to be configured, and making a synthesis of the circuit to be configured on the basis of the function.

In the present case, equations are used which indicate how the input signals of the respective circuits are to be logically linked in order to generate the output signals which are to be respectively generated. However, any desired other functional descriptions, for example transmission functions, can be used.

In an example of this which is described, it is to be assumed that the function of a circuit which is suitable for performing the first task consists in the fact that input signals A, B and C are logically linked in a specific way to form an output signal OUT, that is to say:

OUT=F(A,B,C),

where

F(A,B,C)=m(A,B)*n(A,B,C)

The symbol “*” used in the equation mentioned last defines a logic connection; for the present example it is insignificant which logic connection this is.

It is further to be assumed that the function of a circuit which is suitable for performing the second task consists in the fact that input signals A, B and D are logicly linked in a specific way to form a first output signal OUT1 and to form a second output signal OUT2, that is to say:

{OUT1,OUT2}=G(A,B,D),

to be more precise

OUT1=G1(A,B,D), and

OUT2=G2(A,B,D),

where

G1(A,B,D)=m(A,B)*p(A,B,D), and

G2(A,B,D)=m(A,B)*q(A,B,D);

the symbols “*” in turn designating any desired logic connections.

As is apparent, the functional equations F, G1 and G2 have a common component, namely m(A,B). The circuit part that is to be provided for the implementation of the functional part is a common circuit part that is provided only a single time in the circuit to the configured that is to be able to perform the functions F and G1/G2 on an optional basis.

This is achieved by virtue of the fact that

{F,G}=m(A,B)*z(A,B,C,D,Prog)

is to be used as the functional equation for the circuit to be configured, and the circuit to be configured is to be synthesized therefrom.

The functional part z of the functional equation for the circuit to be configured contains the subfunctions which are not contained both in F and in G (G1 and G2), and can consequently not be implemented by the common circuit parts, that is to say the functions n, p and q, and an additional dependence on a programming signal Prog, by which circuit elements which are to be additionally provided (for example multiplexers) in the circuit to be configured are actuated in such a way that n, p and q are defined as in F, or are logically linked with respect to one another and to m as defined in G (in that the circuit parts which are to be provided for the implementation of the functional parts operate and cooperate either as in the first circuit or as in the second circuit).

A circuit that is configured in this way contains—in contrast to its structure composed of universally usable configurable hardware blocks—no excess circuit parts and makes multiple use of the existing circuit parts as far as possible.

A further possible way of configuring such a circuit is for the method steps mentioned at the beginning for circuit configured, namely identification of those parts of the first circuit which performs only the first task and of the second circuit which performs only the second task which have corresponding functions, and the use of these common circuit parts as a basis for the circuit to be configured. The circuit parts of the first and of the second circuit to which it has not been possible to assign any common circuit part in the respective other circuit is added. Switching elements are added by which the existing circuit parts operate, and are connected, either as in the first circuit or as in the second circuit. On this basis of the configuration, the first circuit performs only the first task, and the second circuit performs only the second task.

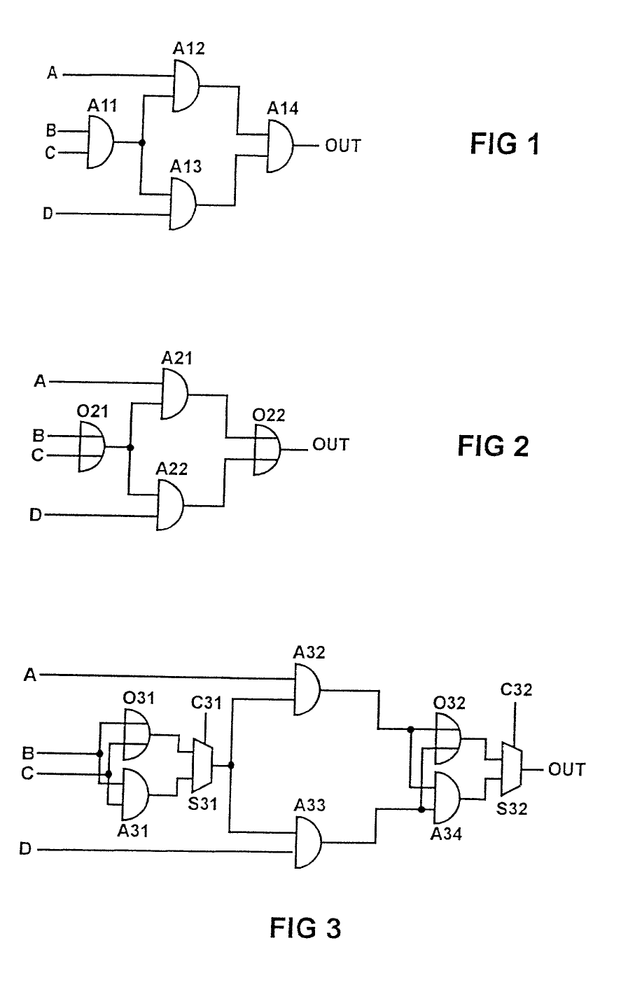

An example of this is described below with reference to FIGS. 1 to 3.

As has already been indicated, the first circuit that performs only the first task and the second circuit that performs only the second task are configured. The first circuit that performs the first task is illustrated in FIG. 1, and the second circuit that performs the second task is illustrated in FIG. 2. In order to avoid misunderstandings, it is to be noted that the circuits shown in FIGS. 1 and 2 do not represent the practical implementation of the functional equations F and G with reference to which a first possible circuit configuration method has been described above.

The circuits shown in FIGS. 1 and 2 are composed of AND gates A11, A12, A13 and A14 (circuit according to FIG. 1) or of AND gates A21 and A22 and OR gates O21 and O22 (circuit according to FIG. 2), which are connected as shown in the respective figures.

As is apparent from FIGS. 1 and 2, the circuits have circuit parts with functions which are identical or which correspond to one another. The AND gates A12 and A13 of the first circuit correspond to the AND gates A21 and A22 of the second circuit.

The corresponding or common circuit parts are to be transferred into the circuit to be configured.

To do this, the circuit parts of the first and second circuits for which there is no circuit part with an identical or corresponding function in the respective other circuit are transferred into the circuit to be configured. In the example in question these are the AND gates A11 and A14 of the first circuit, and the OR gates O21 and O22 of the second circuit.

Furthermore, switching elements S31, S32 are to be added by which the previously mentioned circuit parts of the circuit to be configured operate and cooperate either as in the first circuit or as in the second circuit.

The resulting circuit is illustrated in FIG. 3. It is composed of AND gates A31 to A34, OR gates O31 and O32, and in the example in question the switching elements S31 and S32 formed by multiplexers. The AND gate A32 corresponds to the AND gates A12 and A21, and the AND gate A33 corresponds to the AND gates A13 and A22. The OR element O31 corresponds to the OR element O21, the AND gate A31 corresponds to the AND gate A11, the OR element O32 corresponds to the OR element O22, and the AND gate A34 corresponds to the AND gate A14. The first switching element S31 optionally (as a function of a control signal C31 which controls it) applies the output signal of the OR gate O31 or the output signal of the AND gate A31 to in each case one of the input terminals of the AND gates A32 and A33. The second switching element S32 optionally (as a function of a control signal C32 which controls it) outputs the output signal of the OR gate O32 or the output signal of the AND gate A34 as an output signal from the circuit.

As is apparent from a comparison of the circuits shown in FIGS. 1 and 2 and the circuit shown in FIG. 3, the number of gates in the circuit according to FIG. 3 is smaller than the total number of gates provided in the circuits according to FIGS. 1 and 2. Here, the number of gates in the circuit according to FIG. 3 can be even reduced further: the OR element O31, the AND gate A31 and the switching element S31 on the one hand, and the OR element O32, the AND gate A34 and the switching element S32 on the other can in fact each be combined to form a single element. This element is in each case an adder having three input terminals, the signals B, C, and C31, or the output signals from A32 and A33, and the signal C32 being fed to the input terminals, and the carry bit of the adder being used as the output signal corresponding to the output signal of the switching element S31, or as the output signal corresponding to the output signal of the switching element S32. Such an adder acts as an AND gate for C31=0 or C32=0, and as an OR gate for C31=1 and C32=1.

The circuit according to FIG. 3 has no excess circuit parts and makes multiple use of as many circuit parts as possible so that the existing circuit parts are used to an optimum degree.

It should be clear that there is no restriction requiring the circuit parts used in the circuit configuration to be logic gates. It is also possible to work with relatively large circuit parts (for example with circuit blocks containing a plurality of gates and/or other circuit parts) or with smaller circuit parts (for example individual components such as transistors).

There is also no need to be restricted to identical correspondences when searching for common circuit parts in the first circuit and the second circuit. Circuit parts that “only” correspond to one another are preferably also considered to be common circuit parts. For example, an AND gate whose output terminal has an inverter connected downstream of it corresponds to a NAND gate, or appropriately connected NAND gates may correspond to an AND gate, an OR gate, or a XOR gate.

Moreover, the same applies also to the search for correspondences in the functions of the first circuit that performs the first task, and of the second circuit that performs the second task.

In all the variants of the circuit configuration method described, all the steps can be carried out automatically, for example by an appropriately programmed computer.

The method and device described make it possible, irrespective of the details of the practical implementation, for circuits configured with them not to contain circuit parts that are not required or circuit parts that can be replaced by other existing circuit parts.

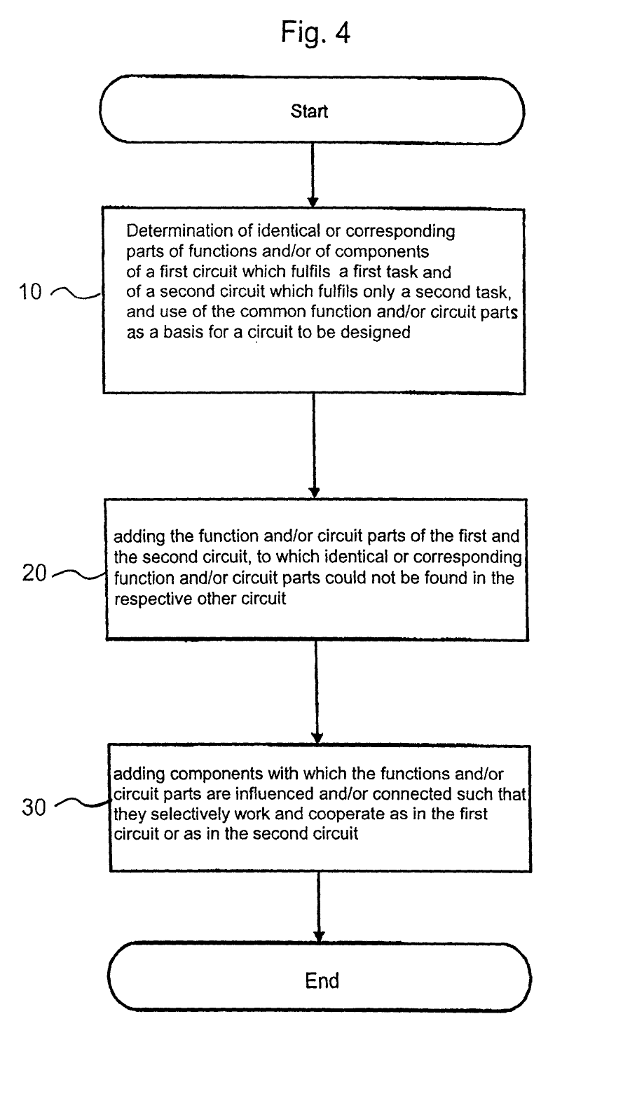

FIG. 4 shows a flow chart highlighting the steps of the invention. The invention can be implemented by a program run by a programmable device such as a computer or an application specific integrated circuit (ASIC). In a first step 10, common identical or corresponding functions and/or circuit parts are determined between a first circuit performing a first task and a second circuit performing a second task. The common functions and/or parts are identified as a basis for a circuit to be configured. In a second step 20, the program identifies functional and/or circuit parts of the first and second circuit, to which identical or corresponding functional and/or circuit parts could not be found in the respective other circuit. These parts are added to the circuit. In a third step 30, components are added with which the functions and/or circuit parts are influenced and/or connected such that they selectively work and cooperated as in the first circuit and as in the second circuit.

I claim:

1. A method for configuring an electrical circuit that can perform optionally a first task and a second task, which comprises the steps of:
identifying at least one of common functional parts and common circuit parts common between a first circuit performing only the first task and a second circuit performing only the second task;
using at least one of the common functional parts and the common circuit parts as a basis for configuring the electrical circuit;
adding at least one of further functional parts and further circuit parts of the first circuit and of the second circuit, which do not belong to the common functional parts and the common circuit parts; and
adding components which at least one of influence and logically link the further functional parts, the further circuit parts, the common functional parts and the common circuit parts in such a way that the parts operate and cooperate so as to perform the functions of the first circuit and of the second circuit.

2. The method according to claim 1, which comprises:
identifying a function of the electrical circuit to be configured; and
making a synthesis of the electrical circuit to be configured on a basis of the function.

3. The method according to claim 1, which comprises identifying the common functional parts and the common circuit parts by the steps of:
designing the first circuit which performs the first task;
designing the second circuit which performs the second task; and
searching through the first and second circuits for circuit parts with identical or corresponding functions.

4. The method according to claim 1, which comprises using switching elements as the components which at least one of influence and logically link the further and common functional parts and the common and further circuit parts.

5. The method according to claim 4, which comprises using multiplexers as the switching elements.

6. A device for configuring an electrical circuit that can perform optionally a first task and a second task, comprising:
means for identifying common functional parts and common circuit parts common between a first circuit performing only the first task and a second circuit performing only the second task, the common functional parts and the common circuit parts are used as a basis for the electrical circuit to be designed;
means for adding further functional parts and further circuit parts of the first and of the second circuit, which do not belong to the common functional parts and the common circuit parts; and
means for adding components which at least one of influence and logically link the further and common functional parts and the further and common circuit parts in such a way that they operate and cooperate so as to perform the functions of the first circuit and of the second circuit.
